(19) United States
(12) Patent Application Publication
(10) Pub. No.: US 2008/0298026 A1
(43) Pub. Date: Dec. 4, 2008

(54) HOLDER FOR ELECTRONIC DEVICE

(75) Inventors: Ming-Jia WANG, Taipei City (TW); Chi-Yen CHIANG, Taipei City (TW)

Correspondence Address: WORKMAN NYDEGGER, 60 EAST SOUTH TEMPLE, 1000 EAGLE GATE TOWER, SALT LAKE CITY, UT, 84111, US

(73) Assignee: MICRO-STAR INT'L CO., LTD., Jung-He City (TW)

(21) Appl. No.: 11/755,860

(22) Filed: May 31, 2007

(51) Int. Cl. H05K 7/00

(52) U.S. Cl. 361/728

(57) ABSTRACT

A holder for a portable electronic device is provided. The holder includes a anchoring portion and two latches to define a clamping area. The anchoring portion and the two latches are respectively disposed at each end of the holder. Each latch has a bent elastic arm and a hook extending from the elastic arm. The two latches are engaged into a fixing hole of the portable electronic device through the hooks, and the two latches provide elastic force in vertical and horizontal directions by the elastic arms. Therefore, the latches may be firmly engaged with the portable electronic device, for preventing latches from being disengaged from the portable electronic device when the holder bears an unexpected external force.

### BACKGROUND OF THE INVENTION

1. Field of the Invention

The present invention relates to a holder, and more particularly to a holder for holding a portable electronic device.

2. Related Art

As the rapid development of science and technology and the popularization of portable electronic products, portable electronic devices, such as GPS navigator, mobile phones, PDAs, portable multimedia players (PMPs), can be installed on a vehicle, which provides plenty of conveniences for the user and facilitates real-time transaction for the user in today's busy and fast-pace economic environment.

Conventional portable electronic devices for vehicles are usually held by hand. For safety, the user has to use a bracket to support the portable electronic device during the drive. However, the bracket only serves for supporting the portable electronic device to rest thereon, instead of fixing the portable electronic device, such as, a navigator. Thus, an expensive portable electronic device might fall off and be damaged due to an accident or the bumpy road.

The conventional bracket can only be used to support the portable electronic device, but cannot fix the portable electronic device. In order to solve the problem that electronic devices cannot be fixed, R.O.C. Taiwan Patent I242509 discloses a fixing device for a portable electronic device for vehicles, in which a second positioning member disposed on the back of the portable electronic device is fixed to a first positioning member by means of fitting through sliding grooves between the second positioning member disposed and the portable electronic device.

In I242509, when fixing or detaching the portable electronic devices, it is required to perform certain actions and accurate alignment, which are not convenient in use. Besides, the portable electronic device is fixed to the fixing device merely through the second positioning member on the back of the portable electronic device in a single axial direction, which is not firm enough to withstand vibrations in all directions during the drive, and thus the portable electronic device is easily shocked or to fall off from the fixing device. As a result, the user has to keep an eye on the portable electronic device, which causes a great threat for the driving safety. Though magnets are added to the fixing device to further enhance the fixing force with the portable electronic device, the user still worries whether the magnetic force is strong enough to hold a large-sized portable electronic device firmly.

R.O.C Taiwan Utility Model M288606 discloses a holder for a portable electronic device, in which a holding block and a retaining clip are disposed on the upper and lower sides of a base, and the holding block is moved to have a certain distance from the retaining clip, so as to fix the portable electronic device in a clamping manner.

Although the holding block in M288606 can firmly clamp the portable electronic device to prevent the portable electronic device from falling off during the drive, it causes inconvenience for the user on removing the portable electronic device from the holder. Particularly, the user has to move the holding block upwards for a certain displacement, for releasing the clamping force at the side of the electronic device, so as to successfully remove the portable electronic device. If the user fails to hold the portable electronic device in time during the process of fixing/removing the portable electronic device, the portable electronic device might fall off and thus being damaged. On the other hand, the appearance of the portable electronic device could be damaged is the clamping force the holder is too large.

The fixing device provided in Patent No. I242509 can fix the portable electronic device by clamping, and it has an advantage of being convenient for the user to fix/remove the portable electronic device, however, this advantage accordingly causes insufficiency of the holding force for the portable electronic device, and thus the electronic device might be easily shocked or fall off. Although the No. M288606 solves the problem of insufficient clamping force of the Patent No. I242509, the clamping force of the holder might be too large, the user has to hold the portable electronic device and meanwhile move the position of the holding block during the process of fix/remove the portable electronic device, which is inconvenient in practical operation.

Though the above two technical means can overcome the technical defaults for each other, they cannot have both the advantages of each other being combined.

### SUMMARY OF THE INVENTION

In view of the above problems, the object of the invention is to provide a holder for solving the problem that the portable electronic device may be easily shocked or fall off from the holder due to that the conventional fixing device or holder utilizing the single axial fixing manner cannot withstand vibrations to the portable electronic devices in all directions. Thus, it is rather dangerous when the portable electronic device used in driving. Furthermore, the conventional fixing device or holder has to be held by both hands when fixing or removing the portable electronic device from the fixing device or holder, which is inconvenient in operation. Moreover, the holding force is difficult to be regulated, which may cause damages to the appearance of the electronic device.

According to the object of the invention, a holder for a portable electronic device of the invention is provided, wherein the portable electronic device has at least one fixing hole formed thereon. The holder includes a base, an anchoring portion, and at least two latches. The anchoring portion is disposed at one end of the base, for anchoring a side edge of the portable electronic device opposite to the fixing hole. The two latches extend from the other end of the base, opposite to the anchoring portion. Each latch has a bent elastic arm and a hook extending from the elastic arm. The hook is provided to be engaged into the fixing hole. The distance between the hooks and the anchoring portion is smaller than that between the fixing hole and the side edge of the portable electronic device, and the distance between the two hooks is larger than the width of the fixing hole, so that the hook can be firmly engaged into the fixing hole by using the elastic arm to generate elastic force to withstand external force.

The advantage of the present invention lies that, the holder provides holding force in the vertical and horizontal directions generated by the elastic arms of the latches to compensate vibrations from all the directions. Thus, crashes occurring between the holder and the portable electronic device are prevented. Moreover, as two hooks are compressed inwards to be engaged into the fixing holes, and the hooks and the anchoring portion stretched and engaged with the portable electronic device generate a reverse holding force, the holder of the present invention can achieve both highly reliable vibration-resistance and clamping effects. Moreover, it is easy for the user to rapidly fixing or removing the portable electronic device, and it is relatively safe during the drive.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1A is an exploded view of a first embodiment of the present invention;

FIG. 1B is a perspective view of the first embodiment of the present invention;

FIG. 1C is a sectional view of the first embodiment of the present invention;

FIG. 2A is an exploded view of a second embodiment of the present invention;

FIG. 2B is a perspective view of the second embodiment of the present invention;

FIG. 2C is a sectional view of the second embodiment of the present invention;

FIG. 3 is a perspective view of a third embodiment of the present invention;

FIG. 4A is an exploded view of a fourth embodiment of the present invention;

FIG. 4B is a perspective view of the fourth embodiment of the present invention; and

FIG. 4C is a sectional view of the fourth embodiment of the present invention.

### DETAILED DESCRIPTION OF THE INVENTION

The holder according to the present invention is used for holding a portable electronic device, and the portable electronic device includes, but not limited to, GPS navigators, PDAs, mobile phones, portable multimedia players (PMPs). In the following detailed description of the present invention, a GPS navigator is taken as a most preferred embodiment of the present invention. However, the appended drawings are only intended for demonstration and as a reference, instead of restricting the present invention.

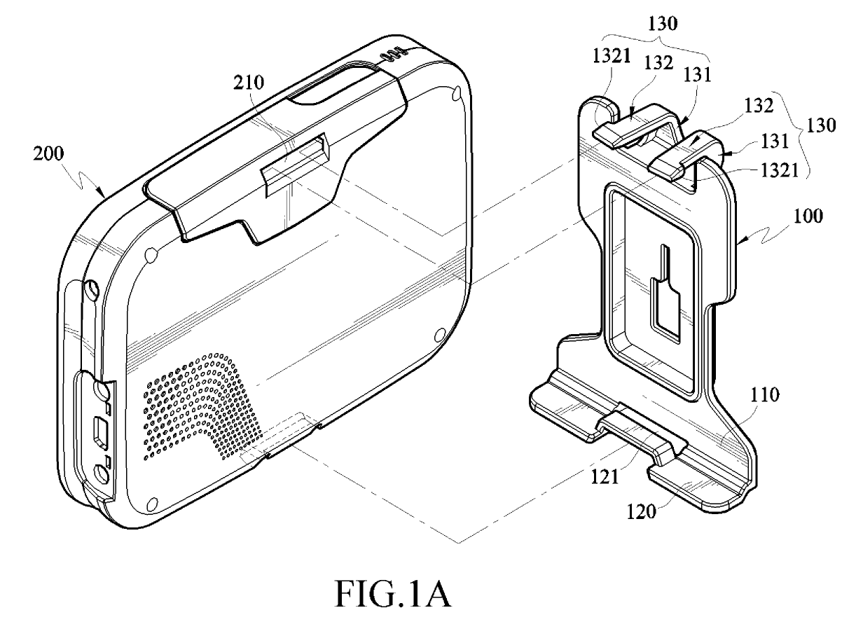

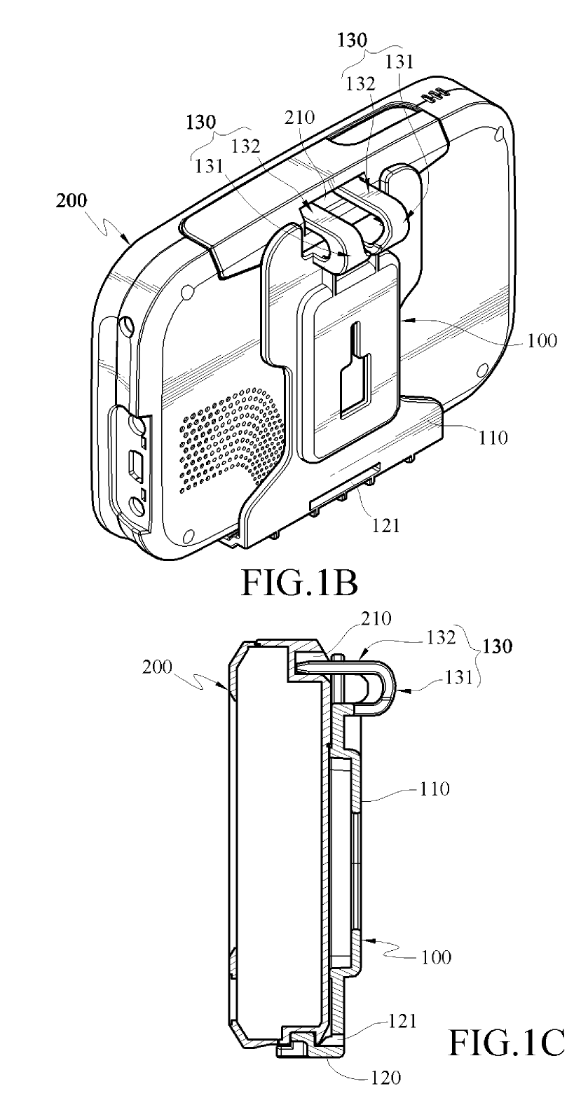

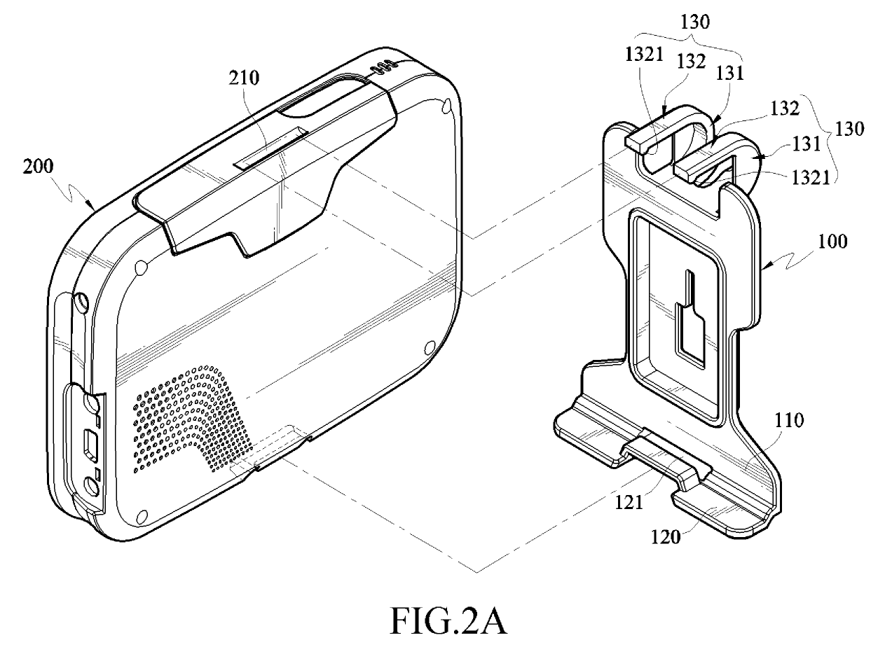

Referring to FIGS. 1A, 1B, and 1C, a holder 100 of the first embodiment of the present invention is provided for holding a portable electronic device 200. The portable electronic device 200 is rectangular-shaped and has two side surfaces and four side edges, in which a display is disposed on one side surface, and a fixing hole 210 formed in the other side surface of the portable electronic device 200.

Referring to FIG. 1A, the holder 100 includes a base 110, an anchoring portion 120, and two latches 130. The base 110 is a long rectangular plate made of a plastic. The anchoring portion 120 is disposed at the lower end of the base 100, and is formed by bending the lower end of the base 110. The anchoring portion 120 is provided for anchoring the lower side edge, opposite to the fixing hole 210, of the portable electronic device 200. The two latches 130 are formed by extending from the other end of the base 110 and being bent, wherein the latching is opposite to the anchoring portion 120, so as to define a clamping area between the anchoring portion 120 and the two latches 130.

The two latches 130 are spaced from each other by a distance, and each includes a bent elastic arm 131 extending upwards from the base 110 and a hook 132 extending from the elastic arm 131. An elastic deformation range is provided between the elastic arms 131 in vertical and horizontal directions, for withstanding external forces, as well as vibrations and crashes occurred between the holder 100 and the portable electronic device 100. The hooks 132 are provided to be engaged into the fixing hole 210 firmly by using the elastic arms 131 to generate elastic force, so as to make the holder 100 be fixed to the back of the portable electronic device 200.

It should be noted that, the present invention takes two latches 130 as a most preferred embodiment for detailed illustration of the present invention, and those skilled in the art can make modifications and design more than two latches 130, which is not limited in the above embodiment.

Referring to FIGS. 1B and 1C, the distance between the hooks 132 of the latches 130 and the anchoring portion 120 is smaller than that between the fixing hole 210 and the lower side of the portable electronic device 200. When the anchoring portion 120 and the two hooks 132 are engaged with the lower side of the portable electronic device 200 and the fixing hole 210 respectively, the base 110 is stretched and extends. Then, the base 110 generates an elastic force in the vertical direction due to the elastic characteristic of its material. And the distance between the two hooks 132 is larger than the width of the fixing hole 210 in the horizontal direction. When the hooks 132 is engaged into the fixing hole 210, the two hooks 132 are respectively compressed inwards corresponding to the width of the fixing hole 210. Moreover, due to the elastic characteristics, the hooks 132 generate an elastic force in the horizontal direction. Because of the elastic deformation of the elastic arms 131, the holder 100 of the present invention generates holding forces in the vertical and horizontal directions, such that the holder 100 can withstand the external vibrations and firmly hold the portable electronic device 200, and thus, preventing the portable electronic device 200 from being shocked or falling off. In addition, when fixing or removing the portable electronic device 200, the only one hand is required for the user to hold the portable electronic device 200, so as to rapidly remove the device 200 from or fix it to the holder 100 in a simple way.

Furthermore, a hook 1321 is formed on the external side of the end portion of each hook 132 to be engaged into the fixing hole 210, for enhancing the fixing force for the hooks 132 to be engaged into the fixing hole 210, so as to prevent the hooks 132 from easily falling out of the fixing hole 210. Moreover, the anchoring portion 120 has an opening 121 for an electric connecting wire (not shown) from an external device to pass through and to be electrically connected to the portable electronic device 200.

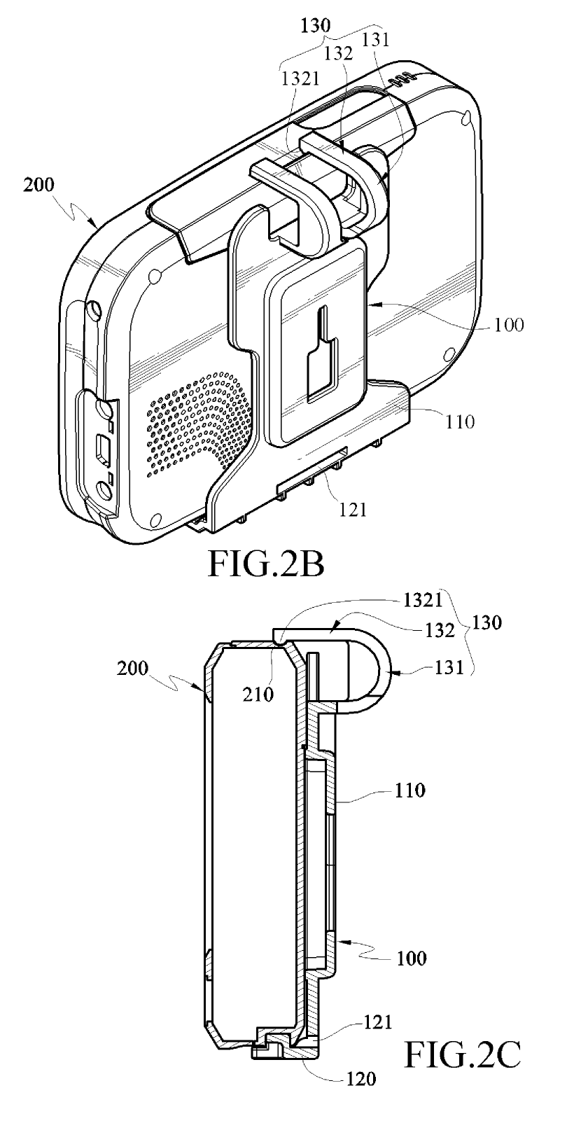

Referring to FIGS. 2A, 2B, and 2C, a holder 100 of a second embodiment of the present invention is provided for holding a portable electronic device 200 having a fixing hole 210 formed on the upper side edge. The distance between the hooks 132 of the latches 130 and the anchoring portion 120 is smaller than that between the upper and lower side edges of the portable electronic device 200. Besides, the distance between the two hooks 132 is larger than the width of the fixing hole 210. When the anchoring portion 120 and the two hooks 132 are engaged with the lower side edge of the portable electronic device 200 and the fixing hole 210 respectively, the base 110 is stretched and extended to an elastic force in the vertical direction. Besides, the two hooks 132 are respectively compressed inwards and engaged into the fixing hole 210. Due to the elastic deformation tolerance generated by the elastic arms 131 and the elastic characteristics of the hooks 132, the hooks 132 generate an elastic force in the horizontal direction, such that the holder 100 can firmly hold the portable electronic device 200.

In addition, a hook 1321 is formed on one side of the end portion of each hook 132 corresponding to the fixing hole 210, for enhancing the holding strength for the hooks 132 to be engaged into the fixing hole 210, so as to prevent the hooks 132 from easily falling out of the fixing hole 210. Moreover, a connection port 121 is further formed on the anchoring portion 120, for an electric connecting wire (not shown) from an external device to pass through and to be further electrically connected to the portable electronic device 200.

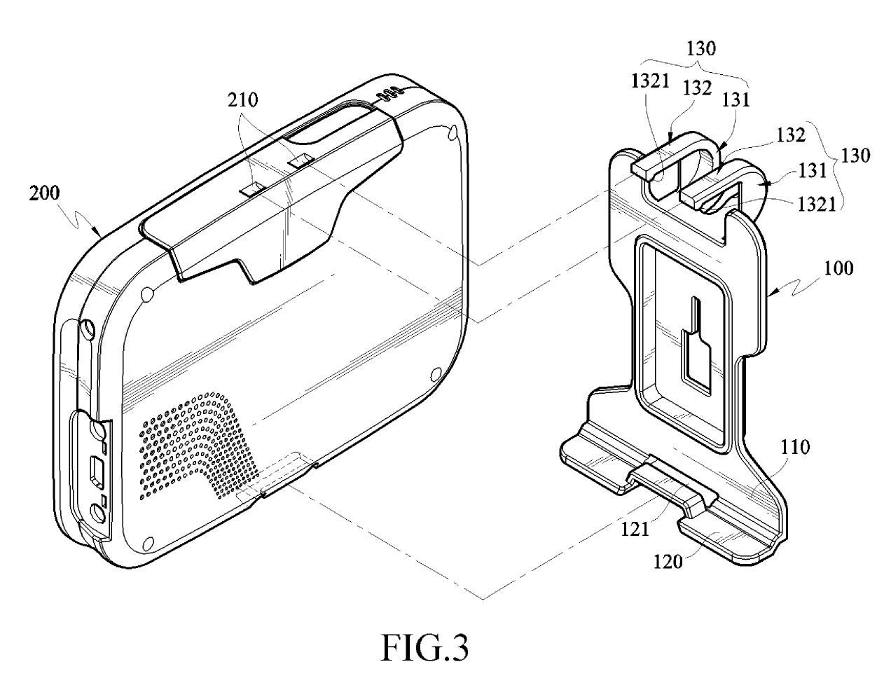

Referring to FIG. 3, A holder 100 of a third embodiment of the present invention is provided for holding a portable electronic device 200 having two fixing holes 210 formed in the upper side surface. The distance between the two hooks 132 is larger than that between the two fixing holes 210, such that the two hooks 132 are compressed inwards and respectively to be engaged into the two fixing holes 210. Due to the elastic characteristic of the elastic arms 131 in the vertical and horizontal directions, the effect of withstanding and counteracting external forces and crashes occurred in all directions is achieved, so that the holder 100 can firmly hold the portable electronic device 200.

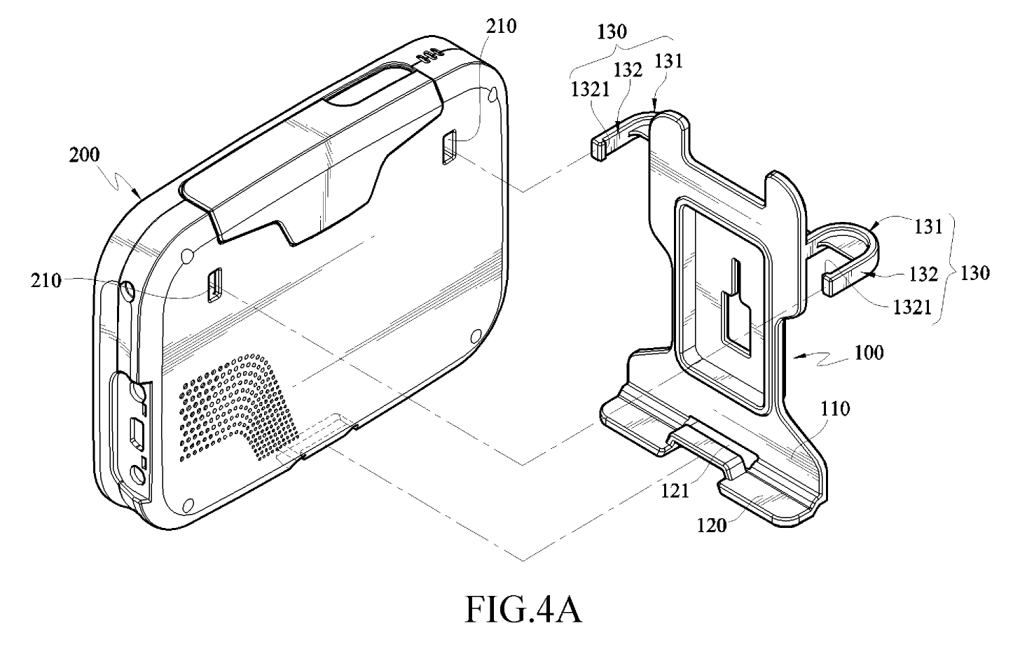

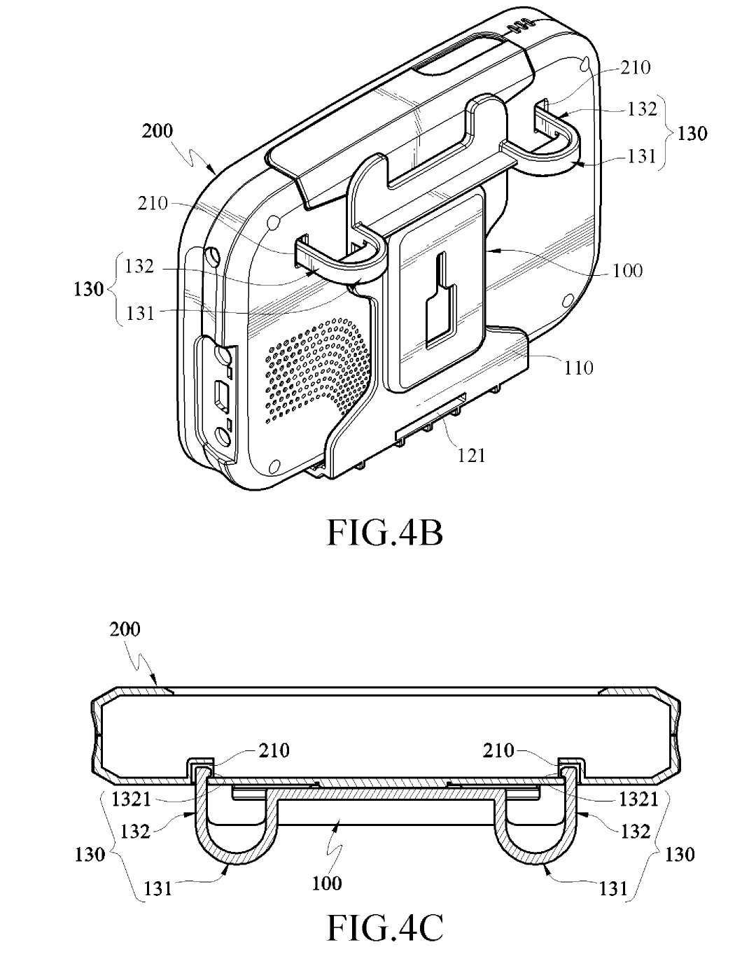

Referring to FIGS. 4A, 4B, and 4C, a holder 100 of a fourth embodiment of the present invention is provided for holding a portable electronic device 200 having two fixing holes 210 spaced from each other by a distance in the back side surface. The anchoring portion 120 and the two latches 130 of the holder 100 are engaged with the lower side edge of the portable electronic device 200 and the fixing hole 210 respectively. Moreover, due to the elastic characteristic of the elastic material of the base 110 and the two hooks 132, as well as the elastic characteristic of the elastic arms 131, external forces and crashes occurred in all directions can be withstood and counteracted, so as to firmly hold the portable electronic device 200, which is convenient for the user to rapidly fix/remove the portable electronic device 200 in a simple way.

In addition, a hook 1321 is formed one side of the end portion of each hook 132 corresponding to the fixing holes 210, for enhancing the holding strength for the hooks 132 to be engaged into the fixing holes 210, so as to prevent the hooks 132 from easily falling out of the fixing holes 210. Moreover, the anchoring portion 120 has a connection port 121 for an electric connecting wire (not shown) of an external device to pass through and to be further electrically connected to the portable electronic device 200.

According to the holder of the present invention, as two hooks, spaced from each other by a distance that is larger than the width of the fixing hole, are compressed inwards to be engaged into the fixing hole, and the hooks and the anchoring portion hook with the portable electronic device to generate a elastic force, the holder can firmly hold the portable electronic device by clamping. Moreover, due to the elastic deformation characteristics of the bent elastic arms of the latches in the vertical and horizontal directions, the holder can withstand and counteract vibrations reaching the electronic device from all directions as well as crashes occurred between the holder and the portable electronic device. Therefore, the holder of the present invention both achieves highly reliable vibration-resistance and clamping effects. Moreover, it is easy for the user to rapidly fix/remove the portable electronic device from the holder, and it is relatively safe during the drive.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A holder for a portable electronic device, wherein the portable electronic device includes at least one fixing hole formed thereon, the holder comprising:
a base;
an anchoring portion, disposed at one end of the base, for anchoring a side edge of the portable electronic device; and
at least two latches, extending from the other end of the base opposite to the anchoring portion, wherein each of the two latches has a bent elastic arm and a hook extending from the elastic arm and the hook is provided to be engaged into the fixing hole firmly by using the elastic arm to generate elastic force to withstand external forces.

2. The holder as claimed in claim 1, wherein a hooking portion is formed on the end of each of the two hooks to be engaged into the fixing hole.

3. The holder as claimed in claim 1, wherein the anchoring portion has an opening for an electric connecting wire to be electrically connected to the portable electronic device.

4. A holder for a portable electronic device, wherein the portable electronic device includes a fixing hole on a side surface, the holder comprising:
a base;
an anchoring portion, disposed at one end of the base, for anchoring a side edge of the portable electronic device opposite to the fixing hole; and
at least two latches, extending from the other end of the base opposite to the anchoring portion, wherein each of the two latches has a bent elastic arm and a hook extending from the elastic arm and the hook is provided to be engaged into the fixing hole firmly by using the elastic arm to generate elastic force to withstand external force;
wherein the distance between the hooks and the anchoring portion is smaller than that between the fixing hole and the side edge of the portable electronic device; and the distance between the two hooks is larger than the width of the fixing hole.

5. The holder as claimed in claim 4, wherein a hooking portion is formed on the end of each of the two hooks to be engaged into the fixing hole.

6. The holder as claimed in claim 4, wherein the anchoring portion has an opening for an electric connecting wire to be electrically connected to the portable electronic device.

7. A holder for a portable electronic device, wherein the portable electronic device includes at least one fixing hole in one side edge, the holder comprising:
a base;
an anchoring portion, disposed on one end of the base, for anchoring a side edge of the portable electronic device opposite to the fixing hole; and
at least two latches, extending from the other end of the base opposite to the anchoring portion, wherein each of the two latches has a bent elastic arm and a hook extending from the elastic arm and the hook is provided to be engaged into the fixing hole firmly by using the elastic arm to generate elastic force to withstand external forces;
wherein the distance between the hooks and the anchoring portion is smaller than that between two side edges of the portable electronic device; and the distance between the two hooks is larger than the width of the fixing hole.

8. The holder as claimed in claim 7, wherein a hooking portion is formed on the end of each of the two hooks to be engaged into the fixing hole.

9. The holder as claimed in claim 7, wherein the anchoring portion has an opening for an electric connecting wire to be electrically connected to the portable electronic device.

10. A holder for a portable electronic device, wherein the portable electronic device includes least two fixing holes in a side surface, the holder comprising:
a base;
an anchoring portion, disposed on one end of the base, for anchoring a side edge of the portable electronic device opposite to the fixing holes; and
at least two latches, extending from the other end of the base opposite to the anchoring portion, wherein each of the two latches has a bent elastic arm and a hook extending from the elastic arm and each hook is engaged into the corresponding fixing hole firmly by using the elastic arm to generate elastic force to withstand external force;
wherein the distance between the two hooks is larger than that between the two fixing holes.

11. The holder as claimed in claim 10, wherein a hooking portion is formed on the end of each of the two hooks to be engaged into the fixing holes.

12. The holder as claimed in claim 10, wherein the anchoring portion has an opening for an electric connecting wire to be electrically connected to the portable electronic device.
